(19) United States
(12) Patent Application Publication
(10) Pub. No.: US 2008/0008271 A1
(43) Pub. Date: Jan. 10, 2008

(54) Dual-system transmitting and receiving device

(75) Inventors: Kwang Du Lee, Damyang-gun (KR); Yu Sin Kim, Daejeon (KR); Sang Gyu Park, Suwon-si (KR); Chang Soo Yang, Seongnam-si (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 11/822,842

(22) Filed: Jul. 10, 2007

(30) Foreign Application Priority Data
Jul. 10, 2006 (KR) 10-2006-0064423

(51) Int. Cl. H03D 3/00; H04L 27/06; H03D 1/00; H03K 9/10

(52) U.S. Cl. 375/340; 375/323; 375/342

(57) ABSTRACT

Provided is a dual-system transmitting device comprising a chaos signal generator that generates a chaos signal; a band-pass filter that filters the generated chaos signal into a signal within an information transmission bandwidth preset in a transmission side; an impulse signal generator that generates an impulse signal synchronized with a transmitted signal; a switching element that selectively outputs the chaos signal passing through the band-pass filter and the generated impulse signal; an amplifier that amplifies the signal selected by the switching element; and a signal transmitting unit that transmits the signal amplified by the amplifier through an antenna. When the signal amplified by the amplifier is a chaos signal, the signal transmitting unit modulates the amplified signal through an OOK (on-off keying) scheme such that the signal is transmitted as a carrier of a transmitted signal. When the signal amplified by the amplifier is an impulse signal, the signal transmitting unit passes the signal to transmit.

Provided is a dual-system receiving device, which is applied to both a received signal using a chaos signal as a carrier and a received signal using an impulse signal as a carrier, the dual-system receiving device comprising a band-pass filter that filters a received signal into a signal within an information transmission bandwidth preset in a reception side; an amplifier that amplifies the filtered received signal; a first demodulator that, when the amplified received signal is a received signal using a chaos signal as a carrier, demodulates the amplified received signal; a second demodulator that, when the amplified received signal is a received signal using an impulse signal as a carrier, demodulates the amplified received signal; and a switching element that selectively outputs the received signal amplified by the amplifier to the first or second demodulator.

### CROSS-REFERENCE TO RELATED APPLICATIONS

This application claims the benefit of Korean Patent Application No. 10-2006-0064423 filed with the Korea Intellectual Property Office on Jul. 10, 2006, the disclosure of which is incorporated herein by reference.

### BACKGROUND OF THE INVENTION

1. Field of the Invention

The present invention relates to a dual-system transmitting and receiving device in which a chaos communication system and an impulse communication system, which are applied to an ultra wide band (hereinafter, referred to as ‘UWB’), are implemented in one chip such that both advantages of the chaos communication system and the impulse communication system can be shared. Further, it is possible to achieve miniaturization and low power.

2. Description of the Related Art

In general, the UWB is referred to as a frequency band where a frequency bandwidth occupies more than 25% of a center frequency or is more than 500 MHz.

When the UWB is observed at a time axis, it can be found that the UWB has a very small signal width. Therefore, the UWB can prevent spreading or superposition of signals, caused by multiple propagation paths, and has a strong characteristic with respect to noise interference. Accordingly, the UWB is widely used in location-awareness communication where high-speed communication and precise distance calculation are required.

As for systems which are widely researched as a communication system using the UWB, there are provided an impulse communication system and a chaos communication system.

The impulse communication system uses an extremely short pulse of less than nano second so as to detect delay time of pulse according to a distance between two communication terminals. Then, the impulse communication system calculates the distance by using the detected delay time.

Since the impulse communication system uses an extremely short pulse, an error in delay time, caused by the spreading of signal, can be reduced. Further, since energy is distributed in a wide band on a spectrum axis, the impulse communication system has low energy density. Therefore, the impulse communication system has little effect upon other systems.

Meanwhile, the chaos communication system uses a chaos signal having a noise characteristic. Typically, a square-wave signal has a regular phase in accordance with time. Therefore, when an interference signal with an antiphase is added, the signal can be distorted or offset. However, since a chaos signal has an aperiodic characteristic like noise, the chaos signal does not have a clear phase. Accordingly, although an antiphase signal or an approximate interference signal is added, interference does not occur.

Further, since the chaos signal has an aperiodic characteristic as described above, the chaos signal has a constant magnitude in a wideband range regardless of a period, when it is analyzed on a frequency axis, which means that the chaos signal has high energy efficiency.

In addition, the chaos communication system uses an on-off keying (OOK) scheme in which a chaos signal within a microwave band is directly modulated using continuous packet information signals of a modem.

The chaos communication system using the OOK scheme, which is a direct modulation scheme, has a few spikes. Therefore, coding such as time hopping or the like is not needed separately in a modem, and circuits such as a phase looked loop (PLL), a mixer, and the like for intermediate-frequency conversion are not needed, which makes it possible to simply implement a transmitting and receiving device.

As described above, a transmitting and receiving device can be simply implemented using the chaos system. Therefore, the chaos communication system can achieve miniaturization and low power which are considered to be important in wireless mobile communication.

FIGS. 1A and 1B are diagram showing the configuration of a transmitting and receiving device of a conventional chaos communication system. FIG. 1A is a diagram showing the configuration of the transmitting device of the chaos communication system. FIG. 1B is a diagram showing the configuration of the receiving device of the chaos communication system.

As shown in FIG. 1A, the transmitting device of the chaos communication system includes a chaos signal generator 11, a band-pass filter 12, an amplifier 13, and an OOK modulator 14.

The chaos signal generator 11 generates a chaos signal, and the band-pass filter filters 12 the generated chaos signal into a signal within an information transmission bandwidth preset in a transmission side.

The amplifier 13 amplifies the filtered chaos signal, and the OOK modulator 14 modulates the amplified chaos signal through the OOK scheme such that the signal can be used as a carrier of a transmitted signal Tx.

As shown in FIG. 1B, the receiving device of the chaos communication system includes a band-pass filter 15, an amplifier 16, an envelope detector 17, a low-pass filter 18, a gain controller 19, and an A/D converter 20.

The band-pass filter 15 filters a received signal Rx into a signal within an information transmission bandwidth preset in a reception side, and the amplifier 16 amplifies the filtered received signal.

Further, the envelope detector 17 detects the magnitude of the amplified received signal through the envelope of the signal, and the low-pass filter 18 eliminates noise included in the received signal output from the envelope detector 17.

The gain controller 19 controls the gain of the signal passing through the low-pass filter 18 such that the signal is included in a level range preset in the reception side, and the A/D converter 20 converts the signal, of which the gain is controlled by the gain controller 19, into a digital signal and demodulates the applied received signal.

FIGS. 2A and 2B are diagrams showing the configuration of a transmitting and receiving device of a conventional impulse communication system. FIG. 2A is a diagram showing the configuration of the transmitting device of the impulse communication system. FIG. 2B is a diagram showing the configuration of the receiving device of the impulse communication system.

As shown in FIG. 2A, the transmitting device of the impulse communication system includes a signal oscillator 21, an impulse signal output unit 22, and an amplifier 23.

The signal oscillator 21 generates a square-wave signal with a constant period, and the impulse signal output unit 22 converts the generated square-wave signal into an impulse signal such that the square-wave signal is synchronized with a transmitted signal Tx and then outputs the impulse signal.

The amplifier 23 amplifies the impulse signal output through the impulse signal output unit 22 and then transmits the amplified impulse signal.

As shown in FIG. 2B, the receiving device of the impulse communication system includes a band-pass filter 24, an amplifier 25, an impulse signal generator 26, a mixer 27, an integrator 28, and an A/D converter 29.

The band-pass filter 24 filters a received signal Rx into a signal within an information transmission bandwidth preset in a reception side, and the amplifier 25 amplifies the filtered received signal.

The impulse signal generator 26 generates an impulse signal synchronized with the received signal, and the mixer 27 correlates the received signal with the impulse signal so as to detect an information signal included in the received signal.

The integrator 28 integrates the detected signal such that the signal is included in a level range preset in the reception side, and the A/D converter 29 converts the integrated signal into a digital signal so as to modulate the applied received signal.

However, in the transmitting and receiving device of the chaos communication system shown in FIGS. 1A and 1B, pulse time is not as short as an impulse signal. Therefore, delay time is caused by spreading of signal, which makes it difficult to accurately calculate a distance between transmitting and receiving terminals and the positions thereof.

In the transmitting and receiving device of the impulse communication system shown in FIGS. 2A and 2B, the processes of generating an impulse signal and performing modulation and demodulation using the signal are needed. Therefore, the system becomes complicated and increases in size. Further, power consumption thereof also increases.

In the above-described communication systems, only one system can be implemented in one chip, which means more than two chips are needed in order to share all advantages of various systems. Therefore, the systems are not suitable for recent wireless mobile communication where miniaturization and low power are required.

### SUMMARY OF THE INVENTION

An advantage of the present invention is that it provides a chaos communication system and an impulse communication system are implemented in one chip using a switching element such that advantages of the chaos communication system and the impulse communication system can be shared. Further, it is possible to achieve miniaturization and low power.

Additional aspect and advantages of the present general inventive concept will be set forth in part in the description which follows and, in part, will be obvious from the description, or may be learned by practice of the general inventive concept.

According to an aspect of the invention, a dual-system transmitting device comprises a chaos signal generator that generates a chaos signal; a band-pass filter that filters the generated chaos signal into a signal within an information transmission bandwidth preset in a transmission side; an impulse signal generator that generates an impulse signal synchronized with a transmitted signal; a switching element that selectively outputs the chaos signal passing through the band-pass filter and the generated impulse signal; an amplifier that amplifies the signal selected by the switching element; and a signal transmitting unit that transmits the signal amplified by the amplifier through an antenna. When the signal amplified by the amplifier is a chaos signal, the signal transmitting unit modulates the amplified signal through an OOK (on-off keying) scheme such that the signal is transmitted as a carrier of a transmitted signal. When the signal amplified by the amplifier is an impulse signal, the signal transmitting unit passes the signal to transmit.

Preferably, the impulse signal generator includes a signal oscillating section that generates a square-wave signal with a constant period; and an impulse signal converting section that converts the square-wave signal into an impulse signal synchronized with a transmitted signal.

According to another aspect of the invention, a dual-system transmitting device comprises a chaos signal generator that generates a chaos signal; a signal oscillator that generates a square-wave signal with a constant period; a switching element that selectively outputs the generated chaos signal and the generated square-wave signal; a modulator that modulates the signal selected by the switching element; a band-pass filter that filters the signal modulated by the modulator into a signal within an information transmission bandwidth preset in a transmission side; and an amplifier that amplifies the filtered signal to transmit. When the signal selected by the switching element is a chaos signal, the modulator modulates the chaos signal by using the chaos signal as a carrier signal of a transmitted signal. When the signal selected by the switching element is a square-wave signal, the modulator modulates the square-wave signal by converting the square-wave signal into an impulse signal synchronized with a transmitted signal.

Preferably, the modulator includes an impulse signal generating section that generates an impulse signal synchronized with a transmitted signal; and a mixer section that mixes the chaos signal and a transmitted signal or mixes the square-wave signal and the impulse signal to perform modulating.

According to a further aspect of the invention, a dual-system receiving device, which is applied to both a received signal using a chaos signal as a carrier and a received signal using an impulse signal as a carrier, comprises a band-pass filter that filters a received signal into a signal within an information transmission bandwidth preset in a reception side; an amplifier that amplifies the filtered received signal; a first demodulator that, when the amplified received signal is a received signal using a chaos signal as a carrier, demodulates the amplified received signal; a second demodulator that, when the amplified received signal is a received signal using an impulse signal as a carrier, demodulates the amplified received signal; and a switching element that selectively outputs the received signal amplified by the amplifier to the first or second demodulator.

Preferably, the first demodulator includes an envelope detecting section that detects the magnitude of the applied received signal through the envelope of the signal; a filter section that eliminates noise included in the received signal output by the envelope detecting section; a gain control section that controls a gain of the signal passing through the filter section such that the signal is included in a level range preset in the reception side; and a first A/D conversion section that converts the signal, of which the gain is controlled by the gain control section, into a digital signal.

Preferably, the filter section is constructed by a low pass filter.

Preferably, the second demodulator includes an information detecting section that generates an impulse signal synchronized with the applied received signal and correlates the received signal with the generated impulse signal so as to detect an information signal included in the received signal; an integrating section that integrates the detected signal such that the signal is included in a level range preset in the reception side; and a second A/D conversion section that converts the integrated signal into a digital signal.

Preferably, the information detecting section includes an impulse signal generator that generates an impulse signal synchronized with the received signal; and a mixer that correlates the received signal with the impulse signal generated by the impulse signal generator so as to detect an information signal included in the received signal.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1A is a diagram showing the configuration of a conventional transmitting device of a chaos communication system;

FIG. 1B is a diagram showing the configuration of a conventional receiving device of a chaos communication system;

FIG. 2A is a diagram showing the configuration of a conventional transmitting device of an impulse communication system;

FIG. 2B is a diagram showing the configuration of a conventional receiving device of an impulse communication system;

FIG. 3 is a diagram showing the configuration of a dual-system transmitting device according to a first embodiment of the invention;

FIG. 4 is a diagram showing the configuration of a dual-system transmitting device according to a second embodiment of the invention; and

FIG. 5 is a diagram showing the configuration of a dual-system receiving device according to the invention.

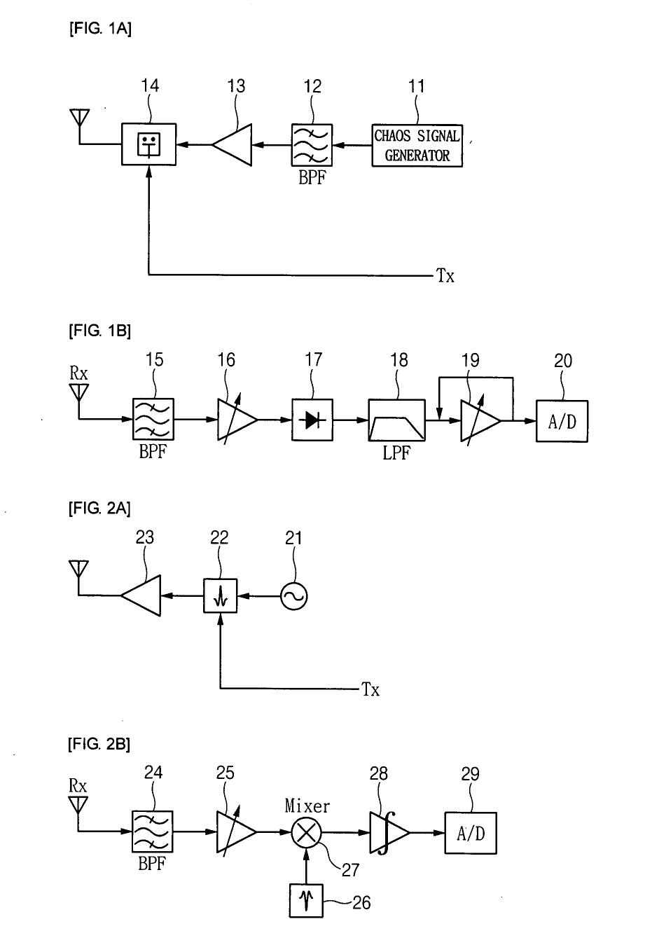

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to like elements throughout. The embodiments are described below in order to explain the present general inventive concept by referring to the figures. In the drawings, the thicknesses of layers and regions are exaggerated for clarity.

Hereinafter, preferred embodiments of the present invention will be described in detail with reference to the accompanying drawings.

### First Embodiment

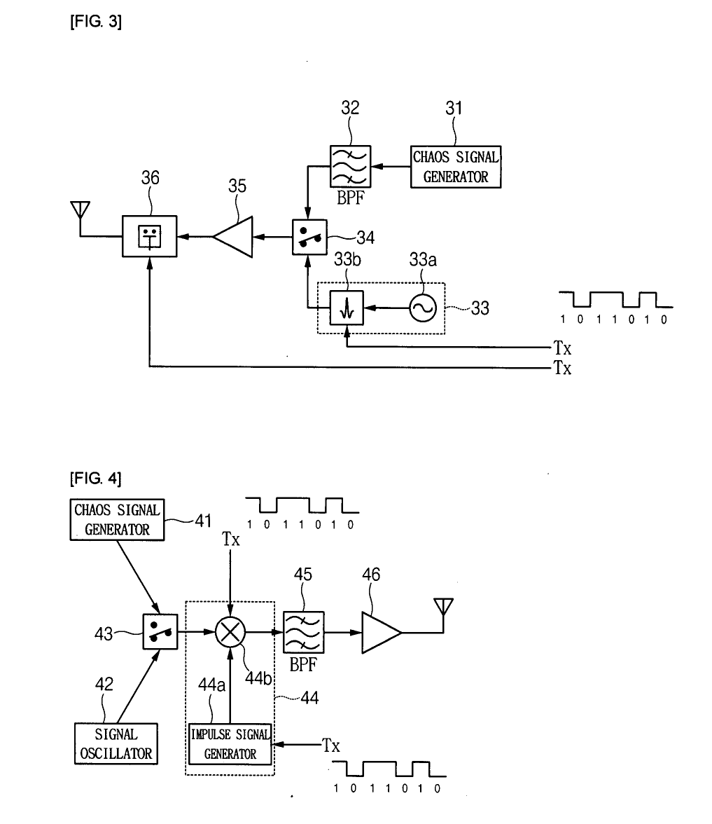

FIG. 3 is a diagram showing the configuration of a dual-system transmitting device according to a first embodiment of the invention. As shown in FIG. 3, the dual-system transmitting device includes a chaos signal generator 31, a band-pass filter 32, an impulse signal generator 33, a switching element 34, an amplifier 35, and a signal transmitting unit 36.

The chaos signal generator 31 generates a chaos signal with a noise characteristic, and the band-pass filter 32 filters the generated chaos signal into a signal within an information transmission bandwidth preset in a transmission side.

The impulse signal generator 33 includes a signal oscillating section 33a and an impulse signal converting section 33b and generates an impulse signal synchronized with a transmitted signal Tx.

The signal oscillating section 33a generates a square-wave signal with a constant period, and the impulse signal converting section 33b converts the generated square-wave signal into an impulse signal synchronized with a transmitted signal Tx and then outputs the impulse signal.

The switching element 34 serving as a dual mode switch selects and outputs any one of the chaos signal passing through the band-pass filter 32 and the impulse signal generated by the impulse signal generator 33, through a switching operation.

The amplifier 35 constructed by a power amplifier amplifies the signal selected by the switching element 34.

The signal transmitting unit 36 constructed by a modulator using an OOK scheme serves to transmit the signal, amplified by the amplifier 35, through an antenna.

When the signal amplified by the amplifier 35 is a chaos signal, the signal transmitting unit 36 modulates the amplified signal through the OOK scheme such that the amplified signal is transmitted as a carrier of a transmitted signal. When the signal amplified by the amplifier 35 is an impulse signal, the signal transmitting unit 36 maintains an on state so as to transmit the amplified signal as it is.

### Second Embodiment

FIG. 4 is a diagram showing the configuration of a dual-system transmitting device according to a second embodiment of the invention. As shown in FIG. 4, the dual-system transmitting device according to the second embodiment includes a chaos signal generator 41, a signal oscillator 42, a switching element 43, a modulator 44, a band-pass filter 45, and an amplifier 46.

The chaos signal generator 41 generates a chaos signal, and the signal oscillator 42 generates a square-wave signal with a constant period.

Similar to that of the first embodiment, the switching element 43 serving as a dual-mode switch selects and outputs any one of the generated chaos signal and square-wave signal, through a switching operation.

The modulator 44 includes an impulse signal generating section 44a, which generates an impulse signal synchronized with a transmitted signal Tx, and a mixer section 44b. The modulator 44 serves to modulate the signal selected by the switching element 43. When the signal selected by the switching element 43 is a chaos signal, the modulator 44 modulates the chaos signal by using the chaos signal as a carrier of a transmitted signal Tx. When the signal selected by the switching element 43 is a square-wave signal, the modulator 44 modulates the square-wave signal by converting the square-wave signal into an impulse signal synchronized with a transmitted signal Tx.

That is, when the switching element 43 selects a chaos signal, the mixer section 44b mixes the chaos signal and a transmitted signal Tx so as to modulate the chaos signal into a carrier of the transmitted signal. When the switching element 43 selects a square-wave signal, the mixer section 44b mixes the square-wave signal with an impulse signal generated by the impulse signal generating section 44a so as to module the square-wave signal.

The band-pass filter 45 filters the signal modulated by the modulator 44 into a signal within an information transmission bandwidth preset in the transmission side, and the amplifier 46 amplifies the filtered signal to transmit.

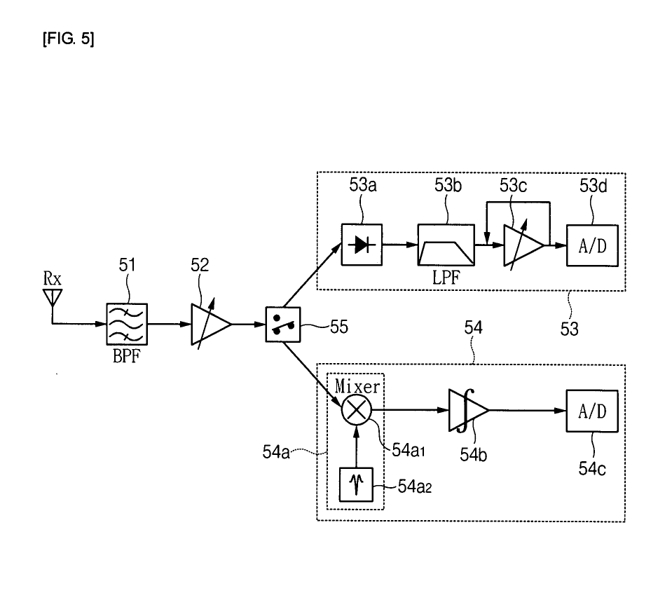

FIG. 5 is a diagram showing the configuration of a dual-system receiving device according to the invention. The dual-system receiving device can be applied to the dual-system transmitting devices of FIGS. 3 and 4.

As shown in FIG. 5, the dual-system receiving device can be applied to both a received signal Rx, in which a chaos signal is used as a carrier, and a received signal Rx in which an impulse signal is used as a carrier. The dual-system receiving device includes a band-pass filter 51, an amplifier 52, a first demodulator 53, a second demodulator 54, and a switching element 55.

The band-pass filter 51 filters a received signal Rx into a signal within an information transmission bandwidth preset in a reception side. The amplifier 52 implemented by a low noise amplifier (LNA) as a variable gain amplifier amplifies the filtered received signal.

The first demodulator 53 includes an envelope detecting section 53a, a filter section 53b, a gain control section 53c, and a first A/D conversion section 53d. When the amplified received signal is a received signal in which a chaos signal is used as a carrier, the first demodulator 53 demodulates the amplified received signal.

The envelope detecting section 53a detects the magnitude of the applied received signal through the envelope of the signal, and the filter section 53b eliminates noise of the received signal output from the envelope detecting section 53a. In this embodiment, the filter section 53b is implemented by a low pass filter (LPF).

The gain control section 53c automatically controls a gain of the signal passing through the low pass filter 53b such that the signal is included in a level range preset in the reception side. The first A/D conversion section 53d converts the signal, of which the gain is controlled by the gain control section 53c, into a digital signal so as to demodulate an information signal included in the received signal.

The second demodulator 54 includes an information detecting section 54a, an integrating section 54b, and a second A/D conversion section 54c. When the amplified received signal is a received signal in which an impulse signal is used as a carrier, the second demodulator 54 demodulates the signal.

The information detecting section 54a includes an impulse signal generator 54a2 and a mixer 54a1. The information detecting section 54a generates an impulse signal synchronized with an applied received signal and correlates the received signal and the generated impulse signal so as to detect an information signal included in the received signal.

The impulse signal generator 54a2 generates an impulse signal synchronized with the received signal, and the mixer 54a1 correlates the received signal with the generated impulse signal so as to detect an information signal included in the received signal.

The integrating section 54b integrates the detected signal such that the detected signal is included in the level range preset in the reception side, and the second A/D conversion section 54c converts the integrated signal into a digital signal so as to detect an information signal included in the received signal.

The switching element 55 also serves as a dual mode switch and selects any one of the first and second demodulators 53 and 54 through a switching operation.

Therefore, the amplified signal by the amplifier 53 is output to the first or second demodulator 53 or 54.

In the invention, the chaos communication system and the impulse communication system are implemented in one chip using the switching element, as described above. Therefore, the advantages of the chaos communication system and the impulse communication system can be all shared.

That is, in a case of communication where location awareness and accurate distance calculation are required, the impulse communication system is adopted, which can measure accurate delay time. In a case of high-speed data communication or normal data communication, the chaos communication system is adopted, which can communicate using low power. Therefore, the advantages of both systems can be shared.

Further, since the chaos communication system and the impulse communication system can be implemented in one chip, it is possible to provide a transmitting and receiving device which corresponds to recent wireless mobile communication in which miniaturization and low power are required.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A dual-system transmitting device comprising:
a chaos signal generator that generates a chaos signal;
a band-pass filter that filters the generated chaos signal into a signal within an information transmission bandwidth preset in a transmission side;
an impulse signal generator that generates an impulse signal synchronized with a transmitted signal;
a switching element that selectively outputs the chaos signal passing through the band-pass filter and the generated impulse signal;
an amplifier that amplifies the signal selected by the switching element; and
a signal transmitting unit that transmits the signal amplified by the amplifier through an antenna,
wherein when the signal amplified by the amplifier is a chaos signal, the signal transmitting unit modulates the amplified signal through an OOK (on-off keying) scheme such that the signal is transmitted as a carrier of a transmitted signal, and
when the signal amplified by the amplifier is an impulse signal, the signal transmitting unit passes the signal to transmit.

2. The dual-system transmitting device according to claim 1,
wherein the impulse signal generator includes a signal oscillating section that generates a square-wave signal with a constant period; and an impulse signal converting section that converts the square-wave signal into an impulse signal synchronized with a transmitted signal.

3. A dual-system transmitting device comprising:
a chaos signal generator that generates a chaos signal;
a signal oscillator that generates a square-wave signal with a constant period;
a switching element that selectively outputs the generated chaos signal and the generated square-wave signal;
a modulator that modulates the signal selected by the switching element;
a band-pass filter that filters the signal modulated by the modulator into a signal within an information transmission bandwidth preset in a transmission side; and
an amplifier that amplifies the filtered signal to transmit,
wherein when the signal selected by the switching element is a chaos signal, the modulator modulates the chaos signal by using the chaos signal as a carrier signal of a transmitted signal, and
when the signal selected by the switching element is a square-wave signal, the modulator modulates the square-wave signal by converting the square-wave signal into an impulse signal synchronized with a transmitted signal.

4. The dual-system transmitting device according to claim 3,
wherein the modulator includes an impulse signal generating section that generates an impulse signal synchronized with a transmitted signal; and a mixer section that mixes the chaos signal and a transmitted signal or mixes the square-wave signal and the impulse signal to perform modulating.

5. A dual-system receiving device which is applied to both a received signal using a chaos signal as a carrier and a received signal using an impulse signal as a carrier, the dual-system receiving device comprising:
a band-pass filter that filters a received signal into a signal within an information transmission bandwidth preset in a reception side;
an amplifier that amplifies the filtered received signal;
a first demodulator that, when the amplified received signal is a received signal using a chaos signal as a carrier, demodulates the amplified received signal;
a second demodulator that, when the amplified received signal is a received signal using an impulse signal as a carrier, demodulates the amplified received signal; and
a switching element that selectively outputs the received signal amplified by the amplifier to the first or second demodulator.

6. The dual-system receiving device according to claim 5,
wherein the first demodulator includes:
an envelope detecting section that detects the magnitude of the applied received signal through the envelope of the signal;
a filter section that eliminates noise included in the received signal output by the envelope detecting section;
a gain control section that controls a gain of the signal passing through the filter section such that the signal is included in a level range preset in the reception side; and
a first A/D conversion section that converts the signal, of which the gain is controlled by the gain control section, into a digital signal.

7. The dual-system receiving device according to claim 6,
wherein the filter section is constructed by a low pass filter.

8. The dual-system receiving device according to claim 5,
wherein the second demodulator includes:
an information detecting section that generates an impulse signal synchronized with the applied received signal and correlates the received signal with the generated impulse signal so as to detect an information signal included in the received signal;
an integrating section that integrates the detected signal such that the signal is included in a level range preset in the reception side; and
a second A/D conversion section that converts the integrated signal into a digital signal.

9. The dual-system receiving device according to claim 8,
wherein the information detecting section includes:
an impulse signal generator that generates an impulse signal synchronized with the received signal; and
a mixer that correlates the received signal with the impulse signal generated by the impulse signal generator so as to detect an information signal included in the received signal.
